(19) United States
(12) Patent Application Publication
(10) Pub. No.: US 2026/0249416 A1
(43) Pub. Date: Aug. 27, 2026

(54) Machine Tool Device, Machine Tool, and Machine Tool System

(71) Applicant: Robert Bosch GmbH, Stuttgart (DE)

(72) Inventors: Florian Esenwein, Leinfelden-Echterdingen (DE); Daniel Barth, Leinfelden-Echterdingen (DE)

(21) Appl. No.: 18/879,341

(22) PCT Filed: Jun. 27, 2023
(86) PCT No.: PCT/EP2023/067376

§ 371 Date: Dec. 27, 2024

(30) Foreign Application Priority Data
Jun. 30, 2022 (DE) 10 2022 206 700.2

(51) Int. Cl. B24B 23/02; B25F 5/02; H05K 1/02

(52) U.S. Cl. CPC B24B 23/028; B25F 5/02; H05K 1/0201

(57) ABSTRACT

The disclosure relates to a machine tool device having a housing unit comprising at least one handle segment and at least one drive segment, having a drive unit for driving a tool, having a tool holder for connecting the tool to the drive unit, having a battery unit for supplying power to the drive unit, and having an electronic unit for controlling the drive unit, the drive unit being disposed in the drive segment and the electronic unit and the battery unit being disposed in the handle segment. It is proposed that a main extension plane of the electronic unit intersects a drive axis of the drive unit on a side facing away from the tool holder.

### PRIOR ART

A machine tool device having a housing unit comprising at least one handle segment and at least one drive segment, having a drive unit for driving a tool, having a tool holder for connecting the tool to the drive unit, having a battery unit for supplying power to the drive unit, and having an electronic unit for controlling the drive unit, the drive unit being disposed in the drive segment and the electronic unit and the battery unit being disposed in the handle segment, has previously been proposed.

### DISCLOSURE OF THE INVENTION

The invention relates to a machine tool device having a housing unit comprising at least one handle segment and at least one drive segment, having a drive unit for driving a tool, having a tool holder for connecting the tool to the drive unit, having a battery unit for supplying power to the drive unit, and having an electronic unit for controlling the drive unit, the drive unit being disposed in the drive segment and the electronic unit and the battery unit being disposed in the handle segment.

It is proposed that a main extension plane of the electronic unit intersects a drive axis of the drive unit on a side facing away from the tool holder.

A “machine tool device” is intended to mean at least one part, in particular a sub-assembly, of a machine tool. The machine tool device may also form the entire machine tool. A “machine tool” is intended to mean a machine for machining workpieces. The machine tool is battery powered and may also be configured to operate when wired in addition to being battery operated. The machine tool is preferably implemented as a portable machine tool, in particular as a hand-held power tool. The term “portable machine tool” is understood in this context to mean a machine tool able to be transported by an operator without the need for a transport machine. In particular, the portable machine tool has a mass of less than 40 kg, preferably less than 10 kg, and particularly preferably less than 5 kg. Preferably, the portable machine tool is configured as a grinding machine, for example, an angle grinder, preferably a burr grinder. Alternatively, however, the portable machine tool may be configured as a cordless screwdriver and/or as a power drill and/or as an impact drill. Further, it is conceivable that the portable machine tool may be configured as a jigsaw, a circular saw, a chainsaw, a grinder, a planing machine, a horticultural machine, a saber saw, or the like. However, it is also conceivable that the portable machine tool has another configuration appearing useful to a person skilled in the art, such as a configuration as a horticultural device, an electric planer, a chipping hammer, or a multifunctional machine.

The housing unit forms an outer housing of the machine tool device, wherein components of the machine tool device that are not part of the housing unit are disposed in and/or on the outer housing of the housing unit in an assembled state of the machine tool device. The housing unit comprises at least one handle segment and at least one drive segment. The handle segment of the housing unit comprises at least one outer contour provided for gripping, in particular gripping around, and holding the housing unit by a user of the machine tool. Preferably, a main direction of extension of the handle segment and a main direction of extension of the drive segment are oriented at an angle to each other, particularly at an angle other than 90.00°.

A “main extension direction” of an object is understood to be a direction running parallel to the longest edge of a smallest geometric cuboid just completely enclosing the object.

A “drive unit” is intended to be a unit for transmitting a kinetic energy by means of an energy conversion, in particular a transformation of an electrical energy into a mechanical energy, to a further, in particular mechanical unit, in particular the tool holder. The further unit can thereby be driven and, in particular, set in motion. The motion may in particular be a rotational motion, a linear motion, a vibrational motion, or a combination of said motions.

The axis of rotation of the drive unit preferably extends at least substantially parallel to a main extension axis of the drive unit. The drive axis may be an axis of rotation about which the drive unit drives the tool in an operating state. Alternatively or additionally, the drive unit may be provided to displace the tool along the drive axis in the operating state, in particular in a linear motion and/or a vibrational motion. Preferably, the drive axis is parallel and centered to a drive shaft and/or drive spindle of the drive unit. Preferably, the drive axis is at least substantially parallel to the main extension direction of the drive segment of the housing unit. “Substantially parallel” is to be understood here in particular to mean an orientation of a direction relative to a reference direction, in particular in a plane, wherein the direction has a deviation relative to the reference direction of in particular less than 8.00°, advantageously less than 5.00°, and particularly advantageously less than 2.00°.

The tool holder is preferably provided for releasably connecting the tool to the drive unit, in particular to the drive shaft and/or drive spindle of the drive unit, and comprises at least one connecting element, preferably a form-fit and/or a force-fit element for this purpose. The tool holder may, for example, be provided for, without being limited thereto, establishing a screw connection and/or a plug connection and/or a latch connection and/or a clamp connection and/or another connection of the tool to the drive unit that appears to be useful to a person skilled in the art. A “tool” is herein to be understood as a tool indirectly or directly disposed on and/or able to be disposed on the machine tool and being at least partially in direct contact with at least one part and/or machining said part in at least one operating state.

A “battery unit” is intended to mean a unit provided for supplying the drive unit with an energy, in particular a chemical and/or preferably an electrical energy, and able to absorb, store, and release said energy, at least at times. For this purpose, the battery unit comprises at least one energy store, in particular a rechargeable battery, for example a lithium-ion battery and/or a lithium polymer battery and/or a nickel-metal hydride battery and/or the like. The rechargeable battery is preferably implemented as a rechargeable battery cell. The battery unit may comprise a plurality of energy stores, in particular rechargeable battery cells. Preferably, the battery unit is provided for providing a peak voltage of at least 12 V in an operating state for supplying energy to the drive unit. The battery unit could alternatively also be provided for providing a lower or higher peak voltage, for example 14 V or 18 V, in the operating state.

The term “electronic unit” refers in particular to a unit having a processor unit and a memory unit as well as to an operating program stored in the memory unit. The electronic unit is provided for controlling the drive unit. In addition, it is also contemplated that the electronic unit may be provided for a control and/or supply of other components of the machine tool, such as display elements, interfaces, or the like. Particularly preferably, the drive unit comprises at least one motor configured as an electronically commutated electric motor, wherein the electronic unit is provided for commutation of the electric motor. Preferably, the electronic unit comprises at least one circuit board on which the processor unit and/or the memory unit are in particular disposed.

The “main extension plane” of a structural unit or an element can be understood to mean a plane parallel to a largest side surface of a smallest possible imaginary cuboid just completely enclosing the structural unit, and in particular extends through the center of the cuboid.

In the present document, numerical words such as “first” and “second” preceding particular terms are merely used in order to distinguish objects from each other and/or associate objects with one another and do not imply an existing total number and/or ranking of the objects. In particular, the term “second object” does not necessarily imply the presence of a “first object”.

The term “intended” should be understood to mean specially configured, specially designed, and/or specially equipped. An object being intended for a particular function is understood to mean that the object fulfills and/or performs said particular function in at least one application and/or operating state.

By the embodiment according to the invention, a machine tool device having advantageous properties with respect to a design can be provided. Advantageously, a particularly compact machine tool device can be provided. At the same time, particularly advantageous ergonomics can be achieved, enabling a particularly convenient, simple, and intuitive operation of the machine tool.

Further, it is proposed that a projection surface of the battery unit projected along an axis of motion of the battery unit has an outline at least substantially enclosing the electronic unit. Advantageously, a particularly compact arrangement can be achieved as a result. An “axis of motion” of the battery unit is to be understood as an axis along which at least a part, in particular at least one battery cell, of the battery unit, preferably the entire battery unit, can be inserted into the handle segment of the housing unit and can be removed from the handle segment of the housing unit. Preferably, the axis of motion of the battery unit is angled relative to the drive axis of the drive unit. The axis of motion of the battery unit is angled relative to the drive axis of the drive unit in particular at an angle of at least 60.00° and at most 120.00°. The axis of motion of the battery unit is angled relative to the drive axis of the drive unit in particular at an angle of at least 60.00°, advantageously of at least 80.00°, particularly advantageously of at least 90.00°, preferably of at least 91.00°, preferably of at least 92.00°, and particularly preferably of at least 93.00°. The axis of motion of the battery unit is angled relative to the drive axis of the drive unit in particular at an angle of at most 120.00°, advantageously of at most 110.00°, particularly advantageously of at most 100.00°, preferably of at most 99.00°, preferably of at most 98.00°, and particularly preferably of at most 97.00°. In a most preferred embodiment, the axis of motion of the battery unit is angled relative to the drive axis of the drive unit at a 95.00°angle. In this context, a “projection surface” of the battery unit is intended to mean a surface of a two-dimensional image of the battery unit resulting from a parallel projection of beams along and/or parallel to the axis of motion of the battery unit. Preferably, the axis of motion of the battery unit is at least substantially parallel to the main direction of extension of the handle segment of the housing unit.

It is also proposed that the main extension plane of the electronic unit is angled relative to the drive axis and to an axis of motion of the battery unit. An advantageously compact embodiment can be achieved by such an embodiment. The main extension plane of the electronic unit is angled relative to the drive axis in particular at an angle of at least 20.00° and at most 85.00°. The main extension plane of the electronic unit is angled relative to the drive axis particularly at an angle of at least 20.00°, advantageously of at least 30.00°, particularly advantageously of at least 40.00°, preferably of at least 50.00°, preferably of at least 60.00°, and particularly preferably of at least 70.00°. The main extension plane of the electronic unit is angled relative to the drive axis particularly at an angle of at most 80.00°, advantageously of at most 77.00°, particularly advantageously of at most 76.00°, preferably of at most 75.00°, preferably of at most 74.00°, and particularly preferably of at most 73.00°. In a most preferred embodiment, the main extension plane of the electronic unit is angled relative to the drive axis at an angle of exactly 72°.

Furthermore, it is proposed that an axis of motion of the battery unit encloses an inclination angle of at least 20.00° and at most 50.00°, particularly of at least 21.00° and at most 46.00°, preferably of at least 22.00°and at most 43.00°, preferably of 23° with the main extension plane of the electronic unit. Advantageously, if the axis of motion of the battery unit encloses an inclination angle of at least 28.00° and at most 50.00° with the main extension plane of the electronic unit, a particularly space-saving arrangement of the electronic unit in the housing unit can be made possible. Smaller inclination angles of at least 20.00, preferably of exactly 23°, may prove to be advantageous, in particular for a space-saving arrangement of particularly large and therefore particularly high-performance electronic units.

Further, it is proposed that the machine tool device has an actuating element disposed on the handle segment for actuating the electronic unit, the actuating element having a greatest length perpendicular to the drive axis and corresponding to at least 25.00% of a greatest length of the handle segment perpendicular to the drive axis. Such an embodiment can advantageously further improve ergonomics and increase user convenience. Advantageously, simple and intuitive operation of the electronic unit can be made possible. In particular, actuation of the electronic unit by means of a plurality of fingers simultaneously is possible if the actuating element comprises a greatest length extending perpendicular to the drive axis corresponding to at least 25.00% of a greatest length of the handle segment extending perpendicular to the drive axis. In particular, the greatest length of the actuating element extending perpendicular to the drive axis corresponds to at least 30.00%, advantageously at least 35.00%, particularly advantageously at least 40.00%, preferably at least 45.00%, and particularly preferably at least 50.00% of the greatest length of the handle segment extending perpendicular to the drive axis.

Furthermore, it is proposed that the electronic unit is bounded by a boundary plane parallel to the drive axis and intersecting the battery unit and/or the actuating element. A compactness can thereby advantageously be further improved. Preferably, the boundary plane intersects both the battery unit and the actuating element. In this context, a “boundary plane” is understood to be an imaginary plane parallel to the drive axis and not having an intersection with the electronic unit.

In addition, it is proposed that the electronic unit is bounded by a further boundary plane extending parallel to the drive axis and intersecting the actuating element. Such a design can advantageously make possible a particularly compact design of the machine tool device. In particular, an optimum arrangement of the electronic unit with respect to the actuating element can be achieved when the electronic unit is bounded by the boundary plane extending parallel to the drive axis and by the further boundary plane extending parallel to the drive axis.

Furthermore, it is proposed that the handle segment has a circumference of at least 130.00 mm and at most 140.00 mm in the region of the actuating element. Such an embodiment can advantageously further improve ergonomics. In particular, a simple gripping of the handle segment in the region of the actuating element and thus a simple actuating of the actuating element can be made possible if the handle segment has a circumference of at least 130.00 mm and at most 140.00 mm in the region of the actuating element. Preferably, the handle segment in the region of the actuating element has a circumference of at least 131.00 mm, preferably of at least 132.00 mm, and particularly preferably of 133.00 mm. In the region of the actuating element, the handle segment in particular has a circumference of at most 139.00 mm, advantageously of at most 138.00 mm, particularly advantageously of at most 137.00 mm, preferably of at most 136.00 mm, preferably of at most 135.00 mm, and particularly preferably of at most 134.00 mm.

It is further proposed that a cross-section of the handle segment in the region of the actuating element is oval and/or polygonal having rounded corners and has a width of at least 35.00 mm and at most 40.00 mm and a height of at least 45.00 mm and at most 50.00 mm. Such an embodiment can advantageously further improve ergonomics. The oval and/or polygonal cross section of the handle segment in the region of the actuating element also advantageously results in an improved, in particular optimal, control for a user of the machine tool device, because the oval and/or polygonal housing shape achieves a positive locking against twisting of the handle segment. The cross section of the handle segment preferably has a width of at least 36.00 mm and at most 39.00 mm in the region of the actuating element, preferably a width of at least 36.50 mm and at most 38.00 mm. The cross section of the handle segment preferably has a height of at least 46.00 mm and at most 49.00 mm in the region of the actuating element, preferably a height of at least 46.50 mm and at most 48.00 mm.

It is also proposed that the electronic unit comprises a circuit board having an outer contour different from a rectangle. An improved arrangement of the electronic unit can thus advantageously be achieved, whereby a particularly compact machine tool device can further advantageously be provided. In particular, a very compact outer contour of the handle segment of the housing unit can be made possible if the electronic unit disposed within the handle segment comprises a circuit board having an outer contour different from a rectangle. The outer contour of the circuit board, different from a rectangle, can be implemented as, without being limited to triangular or trapezoidal or polygonal having more than four corners, for example. The outer contour of the circuit board, different from a rectangle, may be asymmetric and may have the form of a right trapezoid, for example, and not a rectangle. Preferably, the outer contour of the circuit board, different from a rectangle, is symmetric, in particular mirror symmetric, with respect to at least one axis of symmetry, in particular a longitudinal center axis of the circuit board. For example, the outer contour of the circuit board, different from a rectangle, may be the shape of an isosceles triangle or the shape of an isosceles and symmetrical trapezoid, not a rectangle, or may be the shape of a regular polygon having more than four corners and/or may result from a combination of one or more isosceles triangles and/or one or more isosceles and symmetric trapezoids and/or one or more regular polygons having more than four corners. The longitudinal central axis of the circuit board is parallel to a main extension direction of the circuit board. By a symmetrical configuration of the circuit board, a particularly compact and space-saving arrangement in the handle segment can advantageously be made possible. In addition, the housing unit may also have a symmetrical, in particular oval and/or polygon-like cross section in the region of the circuit board, whereby particularly good ergonomics, in particular for both right-handed and left-handed users, can advantageously be achieved.

Furthermore, it is proposed that the circuit board has rounded corners having a radius of 1.00 mm to 4.00 mm. Such an embodiment can advantageously enable a compactness of the circuit board and, consequently, a compactness of the housing unit in a section of the handle region enclosing the electronic unit. In particular, the outer contour of the circuit board can be adapted particularly well to the, preferably oval and/or polygonal, cross section of the handle segment in the region of the actuating element. In particular, the circuit board has rounded corners having a radius of 1.25 mm to 3.75 mm, preferably having a radius of 1.50 mm to 3.50 mm.

In addition, it is proposed that the circuit board has a length of at least 58.00 mm and at most 84.00 mm. A compactness can thereby advantageously be further improved. In particular, the length of the circuit board is at least 60.00 mm, advantageously at least 62.00 mm, particularly advantageously at least 64.00 mm, preferably at least 66.00 mm, preferably at least 68.00 mm, and particularly preferably at least 70.00 mm. In particular, the length of the circuit board is at most at most 83.00 mm, advantageously at most 82.00 mm, particularly advantageously at most 81.00 mm, preferably at most 80.00 mm, preferably at most 77.00 mm, and particularly preferably at most 75.00 mm. In a most preferred configuration, the length of the circuit board is exactly 74.00 mm.

Further, it is proposed that the circuit board has a greatest width of at least 28.00 mm and at most 45.00 mm. A compactness can thereby advantageously be further improved. The greatest width of the circuit board is advantageously at least 29.00 mm, particularly advantageously at least 30.00 mm, preferably at least 31.00 mm, preferably at least 32.00 mm, and particularly preferably at least 33.00 mm. The greatest width of the circuit board is advantageously at most 44.00 mm, particularly advantageously at most 43.00 mm, preferably at most 42.00 mm, preferably at most 41.00 mm, and particularly preferably at most 40.00 mm. In a most preferred configuration, the greatest width of the circuit board is exactly 39.00 mm.

It is also proposed that the circuit board comprises two equally sized first side edges, each having a first angle of at least 13.0° and at most 33.0° with respect to a longitudinal direction of the circuit board. Such a design can advantageously achieve a particularly compact outer contour of the circuit board, whereby in turn a particularly compact outer contour of the housing unit can be achieved advantageously in the section of the handle region enclosing the electronic unit. The two equally sized first side edges each have in particular a first angle of at least 14.0°, advantageously of at least 15.0°, particularly advantageously of at least 16.0°, preferably of at least 17.0°, preferably of at least 18.0°, and particularly preferably of at least 19.0° relative to the longitudinal direction of the circuit board. The two equally sized first side edges each have in particular a first angle relative to the longitudinal direction of the circuit board of at most 32.0°, advantageously of at most 31.0°, particularly advantageously of at most 30.0°, preferably of at most 29.0°, preferably of at most 28.0°, and particularly preferably of at most 27.0°. In a most preferred embodiment, the two equally sized first side edges respectively have a first angle of at least 20°.0 and at most 25.0° relative to the longitudinal direction of the circuit board, preferably a first angle of exactly 23.0°.

Furthermore, it is proposed that the circuit board comprises two equally sized second side edges, each having a second angle of at least 5.0° and at most 25.0° relative to a longitudinal direction of the circuit board. As a result, the outer contour of the circuit board can be made even more compact, which further advantageously results in an even more compact outer contour of the housing unit in the section of the handle region enclosing the electronic unit. The two equally sized second side edges respectively have a second angle relative to the longitudinal direction of the circuit board of at least 6.0°, advantageously of at least 7.0°, particularly advantageously of at least 8.0°, preferably of at least 9.0°, preferably of at least 10.0°, and particularly preferably of at least 11.0°. The two equally sized first side edges each have in particular a second angle relative to the longitudinal direction of the circuit board of at most 24.0°, advantageously of at most 23.0°, particularly advantageously of at most 22.0°, preferably of at most 21.0°, preferably of at most 20.0°, and particularly preferably of at most 19.0°. In a most preferred configuration, the two equally sized first side edges respectively have an angle of at least 12.0°and at most 18.0°, preferably a second angle of exactly 15.0° relative to the longitudinal direction of the circuit board.

Furthermore, it is proposed that the circuit board has a main outer surface area of at least 1850 mm² and at most 2700 mm². Such a configuration can advantageously provide a particularly compact and at the same time particularly high-performance electronic unit. In particular, the circuit board has a main outer surface area of at least 1900 mm², advantageously of at least 1950 mm², particularly advantageously of at least 2000 mm², preferably of at least 2050 mm², and particularly preferably of at least 2100 mm². In particular, the circuit board has a main outer surface area of at most 2650 mm², advantageously of at most 2600 mm², particularly advantageously of at most 2550 mm², preferably of at most 2500 mm², and particularly preferably of at most 2450mm 2. A “main outer surface area” is intended to mean a usable outer surface area of the circuit board on which are placed, in a assembled state of the electronic unit, the electrical and/or electronic components of the electronic unit, for example semiconductor switch elements and capacitors and the like. The main outer surface area of the circuit board encloses at least the two largest surface area sides, in particular a top and a bottom, of the circuit board. Preferably, the inclination angle between the axis of motion of the battery unit and the main extension plane of the electronic unit is adapted to the size of the main outer surface area of the circuit board. For example, the inclination angle between the axis of motion of the battery unit and the main extension plane of the electronic unit is preferably 30.00° in the case of a main outer surface area of the circuit board of 2200 mm², and in the case of a main outer surface area of the circuit board of 1850 mm 2, the inclination angle between the axis of motion of the battery unit and the main extension plane of the electronic unit is preferably 40.00°. In the event of a particularly large main outer surface area of the circuit board of 2700mm², the inclination angle between the axis of motion of the battery unit and the main extension plane of the electronic unit is preferably 22.00°. Advantageously, when the inclination angle between the axis of motion of the battery unit and the main extension plane of the electronic unit is adapted to the size of the main outer surface area of the circuit board, a machine tool device having a smallest possible of the handle segment in the region of the handle segment of the housing unit can be provided with the largest possible main outer surface area of the circuit board. A particularly ergonomic and at the same time particularly high-performance machine tool device can therefore be provided.

In a further consideration of the invention, which can be considered in particular independently as well as in combination with the aforementioned consideration of the invention, it is proposed that the machine tool device comprises a cooling unit for cooling the electronic unit, comprising a main heat sink having a heat sink surface area of greater than 3000 mm². A machine tool device having advantageous properties with respect to a design can be provided by the embodiment according to the invention. Advantageously, a particularly compact machine tool device having advantageously high cooling performance at the same time can be provided. The cooling unit is provided for cooling the electronic unit and may also be provided for cooling further units of the machine tool device, in particular for cooling the battery unit and/or the drive unit. In particular, the main heat sink of the cooling unit has a heat sink surface area of at least 3100 mm², advantageously of at least 3200 mm², particularly advantageously of at least 3300 mm², preferably of at least 3400 mm², preferably of at least 3500 mm² , and particularly preferably of at least 3600 mm². The heat sink surface area of the main heat sink is in particular greater than the main outer surface area of the circuit board of the electronic unit by 10.00%, advantageously by at least 20.00%, particularly advantageously by at least 30.00%, preferably by at least 40.00%, preferably by at least 50.00%, and particularly preferably by at least 60.00%. Preferably, the housing unit comprises at least one air inlet, preferably a plurality of air inlets, and at least one air outlet, preferably a plurality of air outlets. Preferably, the cooling unit comprises at least one fan provided to draw in a cooling air via the at least one air inlet of the housing unit, to transport the cooling air into regions to be cooled within the housing unit, and in particular to pass by the main heat sink and/or an auxiliary heat sink of the cooling unit and to discharge via the at least one air outlet of the housing unit.

It is further proposed that the cooling unit comprises at least one auxiliary heat sink connected to the main heat sink via at least one connecting element. Such an embodiment can advantageously further improve efficiency. Preferably, in an assembled state of the machine tool device, the main heat sink is disposed at least partially on a first side of the circuit board of the electronic unit, preferably on a bottom side of the circuit board facing away from the battery unit in the assembled state. The auxiliary heat sink, in the assembled state of the machine tool device, is preferably disposed at least partially on a second side of the circuit board of the electronic unit opposite to the first side, preferably on a top side of the circuit board facing toward the battery unit. Preferably, the connecting element extends from the main heat sink to the auxiliary heat sink starting from the first side of the circuit board, in particular, from the bottom of the circuit board facing away from the battery unit in the assembled state of the machine tool device, toward the second side of the circuit board, in particular, the top side of the circuit board facing toward the battery unit, namely, in particular, through a pass-through opening in the circuit board, or alternatively, along a side edge of the circuit board. For example, the connecting element may be configured as a heat pipe and/or a copper riser and/or the like, without being limited thereto. In particular, the auxiliary heat sink of the cooling unit has a cooling surface area of at least 300 mm², advantageously of at least 310 mm², particularly advantageously of at least 320 mm², preferably of at least 330 mm², preferably of at least 340 mm², and particularly preferably of at least 350 mm². In addition to the auxiliary heat sink, the cooling unit may comprise at least one further auxiliary heat sink.

In addition, it is proposed that a ratio between the heat sink surface area of the main heat sink and a heat sink surface area of the auxiliary heat sink is at least 10.00 to 1.00. Such a configuration can provide a particularly compact cooling unit having at the same time an advantageously high cooling performance. In particular, the ratio between the heat sink surface area of the main heat sink and the heat sink surface area of the auxiliary heat sink is at least 10.25 to 1, advantageously at least 10.50 to 1, particularly advantageously at least 10.75 to 1, preferably at least 11.00 to 1, preferably at least 11.25 to 1, and particularly preferably at least 11.50 to 1.

Furthermore, it is proposed that the battery unit is configured to provide a continuous power supply to the drive unit at a continuous current of at least 20 A and at most 45 A. Such a configuration can advantageously enable a particularly high level of convenience. The battery unit is in particular designed to provide a continuous power supply of the drive unit at a continuous current of at least 22 A, advantageously of at least 24 A, particularly advantageously of at least 25 A, preferably of at least 26 A, preferably of at least 27 A, and particularly preferably of at least 28 A. The battery unit is in particular designed to provide a continuous power supply of the drive unit at a continuous current of at most 43 A, advantageously of at most 41 A, particularly advantageously of at most 39 A, preferably at most 37 A, preferably at most 35 A, and particularly preferably at most 33 A. In a most preferred configuration, the battery unit is configured to provide a continuous power supply to the drive unit at a continuous current of 28 A.

Moreover, it is proposed that a ratio between a total heat sink surface area of the cooling unit and a continuous current that the battery unit provides for operating the drive unit is at least 100 mm² to 1 A. Such a configuration can enable particularly reliable and safe continuous operation. In particular, a sufficient cooling performance may be provided when the ratio between the total heat sink surface area of the cooling unit and the continuous power provided by the battery unit to operate the drive unit is at least 100 mm² to 1 A. In particular, the ratio between the total heat sink surface area of the cooling unit and the continuous power provided by the battery unit to operate the drive unit is at least 105 mm² to 1 A, advantageously at least 110 mm² to 1 A, particularly advantageously at least 115 mm² to 1 A, preferably at least 120 mm² to 1 A, preferably at least 125 mm² to 1 A, and particularly preferably at least 130 mm² to 1 A. In this context, a “total heat sink surface area” is intended to mean the sum of the individual heat sink surface areas of all heat sinks of the heat sink unit, in particular at least the heat sink surface area of the main heat sink, as well as optionally additionally the heat sink surface area(s) of the auxiliary heat sink or the auxiliary heat sinks.

Further, it is proposed that the drive unit comprises a motor configured as a direct drive and the battery unit is configured to operate the motor continuously for at least 3.00 minutes. Advantageously, a particularly compact design can be made possible at the same time as advantageously high continuous operation time. In this context, a “direct drive” should be understood to mean that the motor is provided for driving the drive shaft and/or the drive spindle of the drive unit to which the tool is connected via the tool holder directly, in particular without an intermediate transmission and/or without an intermediate clutch. The battery unit is in particular configured to provide a continuous operation of the motor of at least 3.25 minutes, advantageously of at least 3.50 minutes, particularly advantageously of at least 3.75 minutes, preferably of at least 4.00 minutes, preferably of at least 4.25 minutes, and particularly preferably of at least 4.50 minutes.

It is also proposed that the motor has a diameter of at least 30.00 mm and at most 48.00 mm perpendicular to a drive axis of the drive unit. Advantageously, a particularly compact machine tool device can be provided by such an embodiment. The motor has a diameter perpendicular to the drive axis of the drive unit of at least 31.00 mm, in particular, advantageously of at least 32.00 mm, particularly advantageously of at least 33.00 mm, preferably of at least 34.00 mm, preferably of at least 35.00 mm, and particularly preferably of at least 36.00 mm. The motor has a diameter perpendicular to the drive axis of the drive unit of at most 45.00 mm, in particular a diameter of at most 44.00 mm, particularly advantageously of at most 43.00 mm, preferably of at most 42.00 mm, preferably of at most 41.00 mm, and particularly preferably of at most 40.00 mm. In a most preferred configuration, the motor has a diameter of 38.00 mm perpendicular to the drive axis of the drive unit.

Furthermore, it is proposed that the motor has a maximum length of at least 17.00 mm and at most 30.00 mm parallel to a drive axis of the drive unit. Advantageously, a particularly compact machine tool device can be provided. The motor has a maximum length of at least 18.00 mm parallel to the drive axis of the drive unit, in particular, advantageously of at least 19.00 mm, particularly advantageously of at least 20.00 mm, preferably of at least 21.00 mm, preferably of at least 22.00 mm, and particularly preferably of at least 23.00 mm. The motor has in particular a maximum length parallel to the drive axis of the drive unit of at most 29.00 mm, advantageously of at most 28.00 mm, preferably of at most 27.00 mm, preferably of at most 26.00 mm, and particularly preferably of at most 25.00 mm. In a most preferred configuration, the motor has a maximum length of 25.00 mm parallel to the drive axis of the drive unit.

For example, the motor of the drive unit could be a brushed DC motor. However, in a particularly preferred configuration, it is proposed that the motor be configured as an electronically commutated electric motor. This can advantageously provide a particularly compact and efficient high-efficiency motor, and thus a particularly efficient machine tool device. Preferably, the electronic unit is provided for commutation of the motor.

Further, it is proposed that the battery unit comprises a plurality of at least three battery cells. This can advantageously provide a high battery power. The battery unit may comprise a plurality of battery cells corresponding to a multiple of three, preferably the double of three.

In a further consideration of the invention, which can in particular be considered independently as well as in combination with the aforementioned considerations of the invention, it is proposed that the housing unit in the drive segment comprises a section tapering in the direction of the tool holder and enclosing an inclination angle of greater than 1.00° and less than 5.00° with a drive axis of the drive unit. A particularly high level of operating convenience can be achieved in an advantageous manner. If the housing unit in the drive segment comprises a section tapering in the direction of the tool holder, enclosing an inclination angle with a drive axis of the drive unit of greater than 1.00° and less than 5.00°, a particularly good view of a tool connected to the tool holder and/or of a part to be machined by means of the tool can advantageously be enabled, whereby user convenience as well as an operating safety can be further advantageously increased. The section in the drive segment of the housing unit tapering in the direction of the tool holder advantageously encloses an inclination angle of greater than 1.25°, particularly advantageously of greater than 1.50°, preferably of greater than 1.75°, preferably of greater than 2.00°, and particularly preferably of greater than 2.25°. The section in the drive segment of the housing unit tapering in the direction of the tool holder encloses, in particular, an inclination angle of less than 4.50°, advantageously of less than 4.00°, particularly advantageously of less than 3.50°, preferably of less than 3.25°, preferably of less than 3.00°, and particularly preferably of less than 2.75°. In a most preferred embodiment, the section in the drive segment of the housing unit tapering in the direction of the tool holder encloses an angle of inclination of exactly 2.50° with the drive axis of the drive unit.

It is further proposed that the drive segment in the direction of view along the drive axis on a side facing away from the tool holder has a ball cap shaped surface area segment, the maximum diameter of which corresponds to a maximum diameter of the tapered section. This can advantageously further increase user convenience. A particularly good view of a part to be machined can advantageously be enabled. By “ball cap shaped” the form of an outer surface area of a ball cap is to be understood. A “ball cap” is intended to be a geometric body, which describes a part of a ball body obtained by intersecting the ball body with a plane and which alternatively is also referred to as a ball segment and/or a ball section and/or a ball callote and/or a ball segment. The machine tool device may comprise a display unit for displaying operational information, for example, a current state of charge of the battery unit and/or a current temperature of the battery unit and/or of the drive unit and/or of the electronic unit and/or a current speed and/or torque of the drive unit and/or the like. Preferably, the display unit comprises at least one display element, for example a display and/or at least one LED and/or the like disposed in the ball cap shaped surface area segment of the housing unit. User convenience can thereby be advantageously further improved. Operational information may be advantageously displayed to a machine user during part machining in a highly visible manner in the ball cap shaped surface area segment.

In addition, it is proposed that the ball cap shaped surface area segment and the tapered section merge into one another. Such a design can advantageously provide a machine tool device having a particularly compact housing unit also characterized by advantageous properties in terms of user convenience and safety of use. That the ball cap shaped surface area segment and the tapered section “merge” should be understood to mean that the ball cap shaped surface area segment has an increasing diameter in the viewing direction along the drive axis toward the tool holder and terminates in the region of the maximum diameter thereof, wherein the tapered section immediately adjoins the end of the ball cap shaped surface area segment and has a maximum diameter at said end, and wherein the diameter of the tapered section decreases in the direction of view along the drive axis in the direction of the tool holder, starting from the end up to a minimum diameter.

Furthermore, it is proposed that the housing unit has a maximum diameter of at most 50.00 mm in the tapered section perpendicular to the drive axis. Such a design advantageously allows a particularly good view of a part to be machined. The housing unit has a diameter in the tapered section perpendicular to the drive axis, in particular, of at most 49.75 mm, advantageously of at most 49.50 mm, advantageously of at most 49.25 mm, preferably of at most 49.00 mm, preferably of at most 48.75 mm, and preferably of at most 48.50 mm.

In addition, it is proposed that the tapered section has a length of at least 44.00 mm along a direction of inclination to the drive axis. This can advantageously allow for an improved view of a part to be machined. The tapered section has a length along the direction of inclination to the drive axis, in particular, of at least 45.00 mm, advantageously of at least 46.00 mm, advantageously of at least 47.00 mm, preferably of at least 48.00 mm, preferably of at least 49.00 mm, and particularly preferably of at least 50.00 mm. The tapered section has a length along the direction of inclination to the drive axis, in particular of at most 56.00 mm, advantageously of at most 55.00 mm, particularly advantageously of at most 54.00 mm, preferably of at most 53.00 mm, preferably of at most 52.00 mm, and particularly preferably of at most 51.00 mm, whereby a compactness of the machine tool device can be advantageously ensured.

Further, it is proposed that the housing unit has a least width in a transition region between the drive segment and the handle section, corresponding to at most 80.0% of a maximum diameter of the tapered section. Such an embodiment can advantageously further improve ergonomics. In the transition region between the drive segment and the handle section, the housing unit has a least width, in particular, corresponding to at most 79.00%, advantageously at most 78.00%, particularly at most 77.00%, preferably at most 76.00%, preferably at most 75.00%, and particularly preferably at most 74.00% of the maximum diameter of the tapered section. Preferably, the housing unit has a neck in the transition region extending perpendicularly in the viewing direction along a whole circumferential direction and having an outer contour, the shape of which at least substantially corresponds to the shape of an ellipse, wherein the least width corresponds in particular to a least diameter of the ellipse.

In addition, it is proposed that the housing unit has a greatest width in the handle segment corresponding to a maximum diameter of the tapered section. Ergonomics can thereby advantageously be further improved. Preferably, the housing unit comprises at least one further tapered section in the handle segment extending from a region of the maximum width of the handle segment toward the drive segment to the transition region having the least width of the housing unit. Ergonomics can thereby advantageously be further improved. In particular, the further tapered section of the housing unit encloses a further inclination angle with the axis of motion of the battery unit of greater than 1.00° and less than 10.00°. Advantageously, the further tapered section encloses a further inclination angle with the axis of motion of the battery unit of greater than 1.50°, particularly advantageously of greater than 2.00°, preferably of greater than 2.50°, preferably of greater than 3.00°, and particularly preferably of greater than 3.50°. The further tapered section encloses in particular a further inclination angle with the axis of motion of the battery unit of less than 9.50°, advantageously of less than 9.00°, particularly advantageously of less than 8.50°, preferably of less than 8.00°, preferably of less than 7.50°, and particularly preferably of less than 7.00°.

Furthermore, it is proposed that the housing unit in the drive segment has a straight end region disposed in the direction of the tool holder below the tapered section, the diameter of which corresponds to a minimum diameter of the tapered section. Such a design can advantageously achieve a particularly high level of flexibility in a design of the machine tool device. The housing unit has a maximum height in the drive segment parallel to the drive axis extending from a bottom edge of the straight end region to a highest point of the ball cap shaped surface area section. Preferably, a height parallel to the drive axis corresponds to at least 50.00%, preferably at least 51.00%, particularly preferably at least 52.00% of the maximum height of the housing unit in the drive segment.

The invention further relates to a machine tool having a machine tool device according to any of the embodiments described above. Such a machine tool is characterized, among other things, by compact dimensions as well as by advantageous ergonomics achieved by the embodiment of the machine tool device according to the invention.

The invention also relates to a machine tool system having the machine tool described above and having at least one tool for releasably connecting to the tool holder. Such a machine tool system is characterized by the advantageous properties of the machine tool achieved by the embodiment of the machine tool device according to the invention, in combination with the tool.

It is also proposed that a maximum diameter of the tool is greater than a maximum diameter of the tapered section in the drive segment of the housing unit. Such a configuration can enable particularly convenient and safe operation of the machine tool system. In particular, if the maximum diameter of the tool is greater than the maximum diameter of the tapered section in the drive segment of the housing unit, a clear view of at least a partial region of the tool and thus a particularly convenient and secure machining of parts can be enabled using the machine tool system. The maximum diameter of the tool is in particular greater than the maximum diameter of the tapered section in the drive segment of the housing unit by at least 1.00%, advantageously by at least 1.50%, particularly advantageously by at least 2.00%, preferably by at least 2.50%, preferably by at least 3.00%, and particularly preferably by at least 3.50%. For example, the tool may have a maximum diameter of at least 50.00 mm.

The machine tool device according to the invention, the machine tool system according to the invention, and the machine tool according to the invention are not limited to the application and embodiment described above. In particular, the machine tool device according to the invention and/or the machine tool system according to the invention and/or the machine tool according to the invention may have a number of individual elements, components, and units differing from a number specified herein in order to fulfill a functionality described herein. Moreover, regarding the ranges of values indicated in this disclosure, values lying within the limits specified hereinabove are also intended to be considered as disclosed and usable as desired.

### DRAWINGS

Further advantages follow from the description of the drawings hereinafter. An exemplary embodiment of the invention is shown in the drawing. The drawings, the description, and the claims contain numerous features in combination. A person skilled in the art will appropriately also consider the features individually and combine them into additional advantageous combinations.

The figures show:

FIG. 1 a machine tool having a machine tool device in a schematic side view,

FIG. 2 a machine tool system having the machine tool and having a tool for releasably connecting to a tool holder of the machine tool device in a schematic cross section view,

FIG. 3 a schematic cross section view through a handle segment of a housing unit of the machine tool device,

FIG. 4 a schematic perspective view of a battery unit and an electronic unit of the machine tool device in the direction of view along an axis of motion of the battery unit,

FIG. 5 a circuit board of the electronic unit in a schematic plan view,

FIG. 6 the machine tool system having the machine tool and the tool in a further schematic side view,

FIG. 7 the machine tool having the machine tool device in a schematic top view,

FIG. 8 the machine tool having the machine tool device in a further schematic cross section view; and

FIG. 9 a main heat sink of a cooling unit of the machine tool device for cooling the electronic unit in a schematic perspective view.

### DESCRIPTION OF THE EXEMPLARY EMBODIMENT

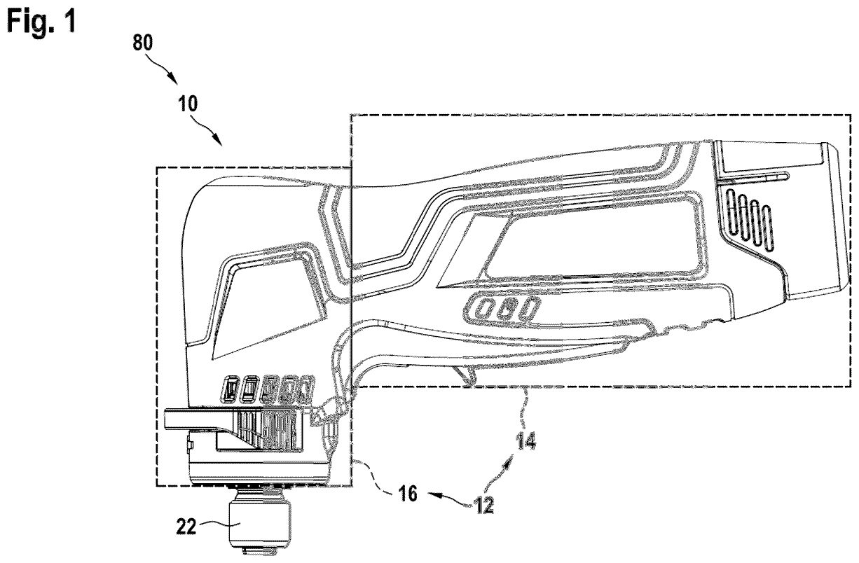

FIG. 1 shows a machine tool 80 in a perspective view. In the present embodiment, the machine tool 80 is configured as a burr grinder.

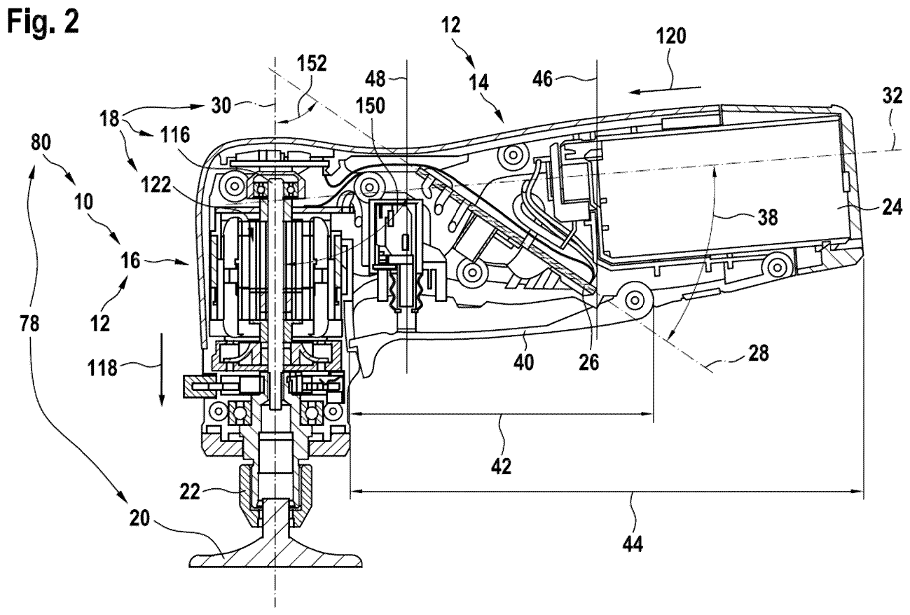

The machine tool 80 comprises a machine tool device 10. The machine tool device 10 comprises a housing unit 12 comprising at least one handle segment 14 and at least one drive segment 16. The machine tool device 10 comprises a drive unit 18 for driving a tool 20 (cf. FIG. 2). The machine tool device 10 comprises a tool holder 22 for connecting the tool 20 to the drive unit 18.

The machine tool 80 is part of a machine tool system 78. The machine tool system 78 comprises the machine tool 80 having the machine tool device 10 and at least the tool 20 (cf. FIG. 2) for connecting to the tool holder 22 of the machine tool device 10.

FIG. 2 shows machine tool system 78 in a schematic cross section view having the tool machine 80 comprising the machine tool device 10, and having the tool 20, said tool 20 being releasably connected to the tool holder 22. The tool 20 is implemented here as a grinding tool. The machine tool system 78 may include additional tools (not shown) in addition to the tool 20 for connecting to the tool holder 22.

In FIG. 2, the drive unit 18 of the machine tool device 10 is shown. The drive unit 18 comprises a drive spindle 116 and a motor 122 for driving the drive spindle 116. The tool holder 22 is connected to the drive spindle 116. In an operating state of the machine tool device 10, the motor 122 generates rotational motion of the drive spindle 116 along with the tool holder 22 and the tool 20 connected to the tool holder 22 about a drive axis 30 of the drive unit 18. In the present case, the drive axis 30 is oriented parallel and centered to the drive spindle 116.

In the present case, a main direction of extension 118 of the drive segment 14 of the housing unit 12 is parallel to the drive axis 30 of the drive unit 18.

The machine tool device 10 further comprises a battery unit 24 for supplying power to the drive unit 18.

The machine tool device 10 also comprises an electronic unit 26 for controlling the drive unit 18. The drive unit 18 is disposed in the drive segment 16. The electronic unit 26 and the battery unit 24 are disposed in the handle segment 14.

A main extension plane 28 of the electronic unit 26 intersects the drive axis 30 of the drive unit 18 on a side of the drive unit 18 facing away from the tool holder 22.

The main extension plane 28 of the electronic unit 26 is angled relative to the drive axis 30 and an axis of motion 32 of the battery unit 24. Along the axis of motion 32, the battery unit 24 can be inserted into the handle segment 14 of the housing unit 12 and pulled out of the handle segment 14 of the housing unit 12.

The main extension plane 28 of the electronic unit 26 is angled to the drive axis 30 of the drive unit 18 at an angle 152, in the present case 55.00°.

The axis of motion 32 of the battery unit 24 encloses an inclination angle 38 with the main extension plane 28 of the electronic unit 26 of at least 20° and at most 50.00°, particularly of at least 21.00° and at most 46.00°, preferably of at least 22.00° and at most 43.00°, preferably of 23.00°. In the present case, the inclination angle 38 of the axis of motion 32 of the battery unit 24 with the main extension plane 28 of the electronic unit 26 is 23.00°.

The axis of motion 32 of the battery unit 24 is angled relative to the drive axis 30 of the drive unit 18 at an angle 150 of at least 60.00° and at most 120.00°. In the present case, the axis of motion 32 of the battery unit 24 is angled relative to the drive axis 30 of the drive unit 18 at the angle 150 of 95.00°.

In the present case, a main direction of extension 120 of the handle segment 14 of the housing unit 12 runs parallel to the axis of motion 32 of the battery unit 24.

The machine tool device 10 comprises an actuating element 40 disposed on the handle segment 14 for actuating the electronic unit 26. The actuating element 40 has a greatest length 42 extending perpendicular to the drive axis 30. The greatest length 42 of the actuating element 40 corresponds to at least 25.00% of a greatest length 44 of the handle segment 14 extending perpendicular to the drive axis 30. In the present case, the greatest length 42 of the actuating element 40 corresponds to about 60.00% of the greatest length 44 of the handle segment 14. The greatest length 44 of the handle segment 14 in the present case is, for example, about 156 mm and the greatest length 42 of the actuating element 40 in the present case is about 95 mm.

The electronic unit 26 is bounded by a boundary plane 46 running parallel to the drive axis 30. The boundary plane 46 intersects the battery unit 24 and/or the actuating element 40. In the present case, the boundary plane 46 intersects the battery unit 24 and the actuating element 40.

The electronic unit 26 is also bounded by a further boundary plane 48 extending parallel to the drive axis 30 and intersecting the actuating element 40. The boundary plane 46 and the further boundary plane 48 are respectively considered planes that do not have an intersection point with the electronic unit 26.

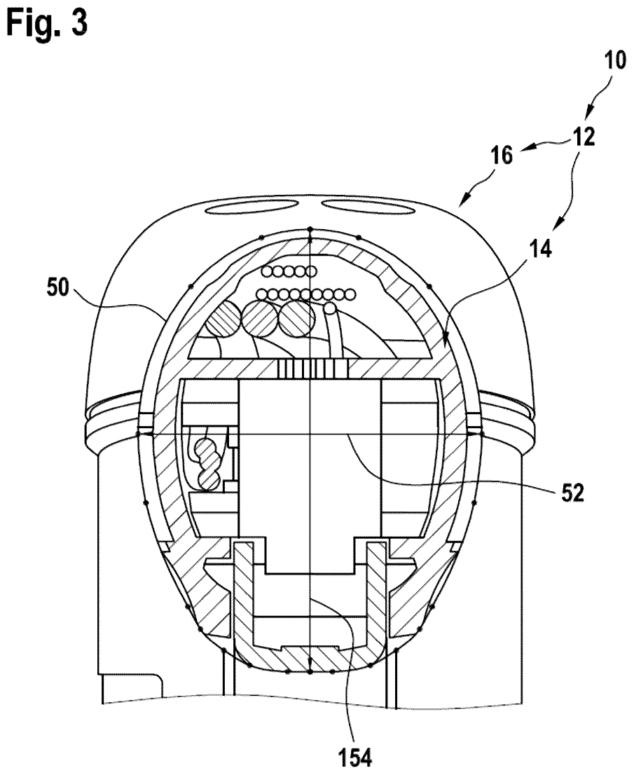

FIG. 3 shows a schematic cross section of the housing unit 12 having a cross section through the handle segment 14 in the region of the actuating element 40. In the region of the actuating element 40, the cross section of the handle segment 14 is oval and/or polygonal having rounded corners. In the present case, the cross-section of the handle segment 14 is oval shaped in the region of the actuating element 40. The cross section of the handle segment 14 has a width 52 in the region of the actuating element 40 of at least 35.00 mm and at most 40.00 mm. In the present case, the width 52 of the cross section is 37.00 mm. The cross section of the handle segment 14 has a height 154 of at least 45.00 mm and at most 50.00 mm in the region of the actuating element 40. In the present case, the height 154 of the cross section is 47.00 mm.

The handle segment 14 has a circumference 50 of at least 130 mm and at most 140 mm in the region of the actuating element 40. In the present case, the circumference 50 of the handle segment 14 in the region of the actuating element 40 is 133.00 mm.

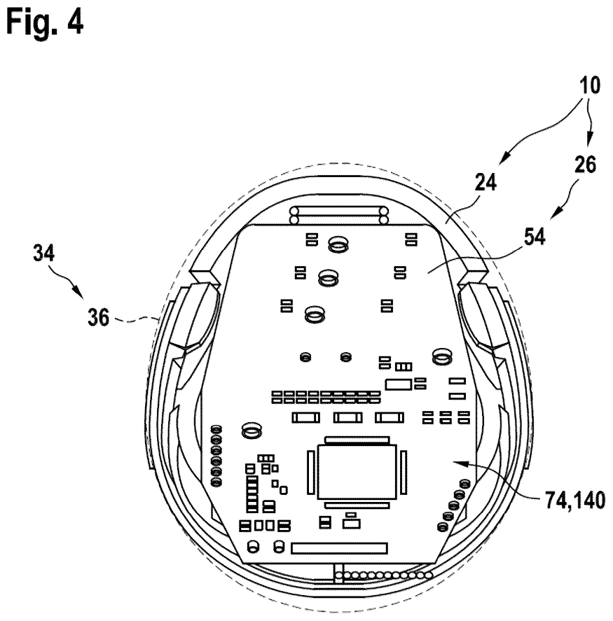

FIG. 4 shows the battery unit 24 and the electronic unit 26 in a schematic perspective view in the direction of view along the axis of motion 32 (cf. FIG. 2) of the battery unit 24.

A projection surface 34 of the battery unit 24 projected along the axis of motion 32 of the battery unit 24 has an outline 36 at least substantially enclosing the electronic unit 26. In the present case, the outline 36 of the projection surface area 34 of the battery unit 24 completely encloses the electronic unit 26.

The electronic unit 26 comprises a circuit board 54. In FIG. 4, a bottom 140 of the circuit board 54 is shown.

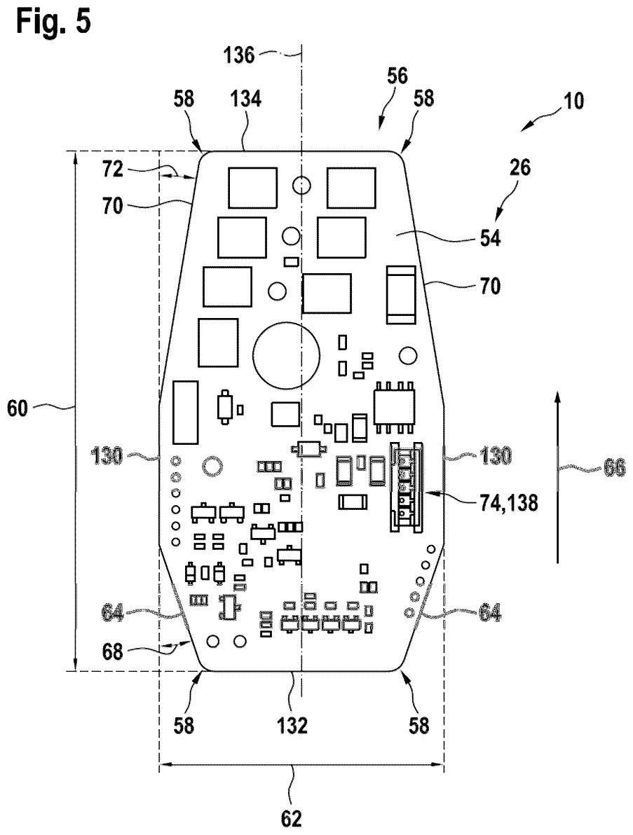

In FIG. 5, the circuit board 54 is shown in a schematic plan view of a top side 138. The circuit board 54 has an outer contour 56 different from a rectangle. In the present case, the outer contour 56 of the circuit board 54 is octagonal.

The circuit board 54 has a length 60 of at least 58.00 mm and at most 84.00 mm. In the present case, the length 60 of the circuit board 54 is 74.00 mm.

The circuit board 54 has a greatest width 62 of at least 28.00 mm and at most 45.00 mm. In the present case, the greatest width 62 of the circuit board 54 is 39.00 mm.

The circuit board 54 has two equally sized first side edges 64. The first side edges 64 each have a first angle 68 of at least 13.00° and at most 33.00° with respect to a longitudinal direction 66 of the circuit board 54. In the present case, the first angle 68 of the first side edges 64 is 23.00° with respect to the longitudinal direction 66.

The circuit board 54 further has two equally sized second side edges 70. The second side edges 70 each have a second angle 72 of at least 5.00° and no more than 25.00° with respect to the longitudinal direction 66 of the circuit board. In the present case, the second angle 72 of the second side edges 70 is 15.00° each.

The circuit board 54 further comprises two equally sized middle edges 130 running parallel to the longitudinal direction 66. Each of the center edges 130 connects one of the first side edges 64 to one of the second side edges 70. The circuit board 54 also has a bottom edge 132 and a top edge 134. The bottom edge 132 and the top edge 134 of the circuit board 54 are each aligned perpendicular to the longitudinal direction 66. In the present case, the bottom edge 132 and the top edge 134 are the same size. The bottom edge 132 connects the two first side edges 64 to each other. The top edge 134 connects the two second side edges 70 to each other. In the present case, the circuit board 54 is configured to be mirror-symmetrical about the longitudinal center axis 136 running parallel to the longitudinal direction 66.

The circuit board 54 has rounded corners 58. Each of the rounded corners 58 of the circuit board 54 connects one of the two first side edges 64 to the bottom edge 132. Each of the rounded corners 58 of the circuit board 54 connects one of the two second side edges 70 to the top edge 134. The rounded corners 58 of the circuit board 54 have a radius of 1.00 mm to 4.00 mm.

The circuit board 54 has a main outer surface area 74 of at least 1850 mm² and at most 2700 mm². The main outer surface area 74 comprises a surface area of a top side 138 of the circuit board 54 and a surface area of a bottom side 140 (cf. FIG. 4).

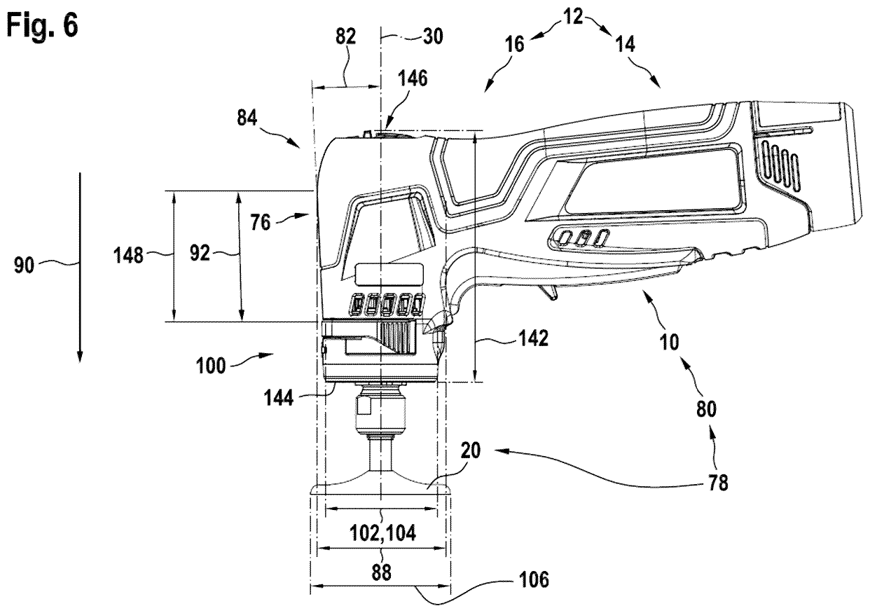

FIG. 6 shows a further schematic view of machine tool system 78 having the machine tool 80 comprising the machine tool device 10 and having the tool 20.

The housing unit 12 has a section 76 in the drive segment 16 tapering in the direction of the tool holder 22. The tapered section 76 encloses an inclination angle 82 with the drive axis 30 of the drive unit 18. The inclination angle 82 is greater than 1.00° and less than 5.00°. In the present case, the inclination angle 82 is approximately 2.50°.

The housing unit 12 has a maximum diameter 88 of at most 50.00 mm perpendicular to the drive axis 30 in the tapered section 76. In the present case, the maximum diameter 88 in the tapered section 76 is approximately 48.00 mm.

The tapered section 76 has a length 92 of at least 44.00 mm along an inclination direction 90 relative to the drive axis 30. In the present case, the length 92 of the tapered section 76 has a length of exactly 50.00 mm.

The housing unit 12 has a straight end region 100 disposed in the drive segment 16 in the direction of the tool holder 22 below the tapered section 76. A diameter 102 of the straight end region 100 corresponds to a minimum diameter 104 of the tapered section 76. In the present case, the diameter 102 of the straight end region 100 and the minimum diameter 104 of the tapered section 76 are each approximately 44.00 mm.

The drive segment 16 of the housing unit 12 has a ball cap shaped surface area segment 84 in the direction of view along the drive axis 30 on a side facing away from the tool holder 22.

The housing unit 12 has a maximum height 142 in the drive segment 16. The maximum height 142 extends from a bottom edge 144 of the straight end region 100 to a highest point 146 of the ball cap shaped surface area segment 84. In the present case, the housing unit 12 in the drive segment 16 has a maximum height 142 of 96.00 mm.

A height 148 of the tapered section 76 corresponds to at least 50.00% of the maximum height 142 of the housing unit 12 in the drive segment 16. In the present case, the height 148 of the tapered section 76 has a length of 49.95 mm and corresponds to at least 52.00% of the maximum height 142 of the housing unit 12 in the drive segment 16.

A maximum diameter 106 of the tool 20 of the machine tool system 78 is greater than the maximum diameter 88 of the tapered section 76 in the drive segment 16 of the housing unit 12. Thus, a user of the machine tool system 78 can be provided with good visibility of the tool 20 in the direction of view parallel to the drive axis 30.

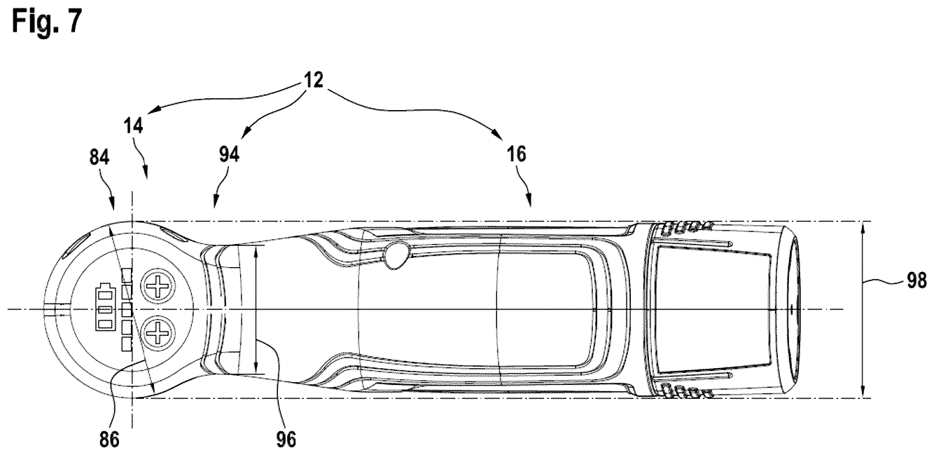

FIG. 7 shows a schematic plan view of the housing unit 12 in the direction of view along the drive axis 30 (cf. FIG. 6). A maximum diameter 86 of the ball cap shaped surface area segment 84 corresponds to a maximum diameter 88 (cf. FIG. 6) of the tapered section 76. As can be seen from FIG. 6, the ball cap shaped surface area segment 84 and the tapered section 76 merge into one another.

The housing unit 12 has a least width 96 in a transition region 94 between the drive segment 16 and the handle segment 14. The least width 96 of the housing unit 12 in the transition region 94 between the drive segment 16 and the handle segment 14 corresponds to a maximum of 80.00% of the maximum diameter 88 of the tapered section 76 (cf. FIG. 6). In the present case, the least width 96 of the housing unit 12 in the transition region 94 between the drive segment 16 and the handle segment 14 corresponds to approximately 73.00% of the maximum diameter 88 of the tapered section 76 and thus approximately 35.00 mm.

The housing unit 12 has a greatest width 98 in the handle segment 14. The greatest width 98 of the housing unit 12 in the handle segment 14 corresponds to at most the maximum diameter 88 of the tapered section 76.

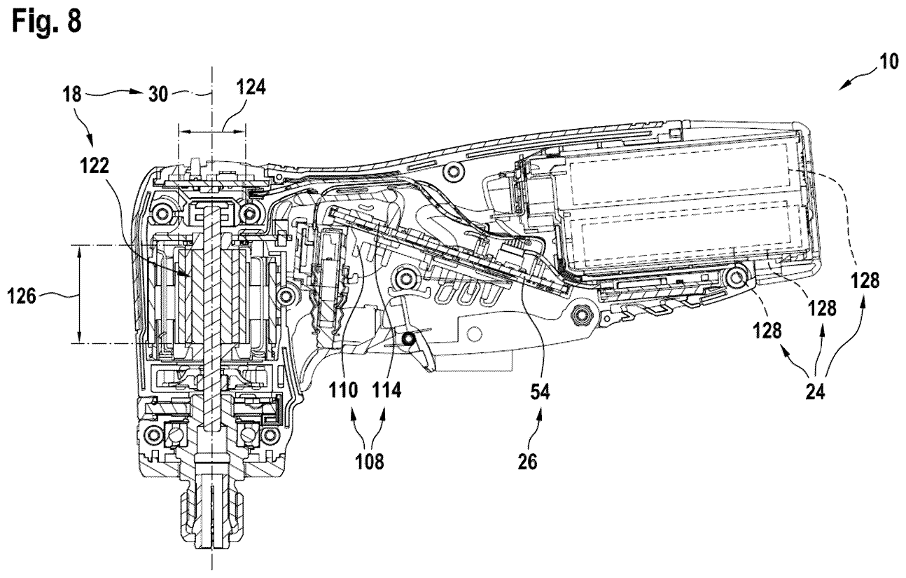

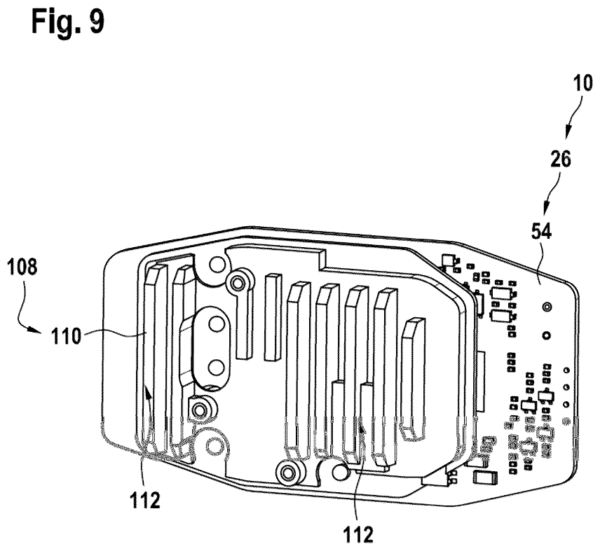

FIG. 8 shows the machine tool device 10 in a further schematic cross section view. The machine tool device 10 comprises a cooling unit 108 for cooling the electronic unit 26. The cooling unit 108 comprises a main heat sink 110. The main heat sink 110 has a heat sink surface area 112 (cf. FIG. 9) of greater than 3000mm². In an assembled state of the cooling unit 108, the main heat sink 110 is present at the bottom 140 (cf. FIG. 4) of the circuit board 54 of the electronic unit 26.

The cooling unit 108 comprises at least one auxiliary heat sink 114 connected to the main heat sink 110 via at least one connecting element (not shown). In the assembled state of the cooling unit 108, the main heat sink 110 and the auxiliary heat sink 114 are disposed on opposite sides of the electronic unit 26. In the present case, the main heat sink 110 is therefore present on the bottom side 140 (cf. FIG. 4) of the circuit board 54 of the electronic unit 26 and the auxiliary heat sink 114 is located on the top side 138 opposite the bottom side 140 (cf. FIG. 5) of the circuit board 54 of the electronic unit 26. For example, the connection element by means of which the auxiliary heat sink 114 is connected to the main heat sink 110 may be configured as a heat pipe extending through the circuit board 54 of the electronic unit 26. An amount of heat generated at the electronic unit 26 in an operating state of the machine tool device 10 is initially predominantly delivered via the main heat sink 110 and partially transported via the connecting element to the auxiliary heat sink 114 to further increase a cooling performance.

A ratio between the heat sink surface area 112 of the main heat sink 110 and a heat sink surface area (not shown) of the auxiliary heat sink 114 is at least 10 to 1. The heat sink surface area of the auxiliary heat sink corresponds to at least 300 mm², in the present case exactly 300 mm². The ratio between the heat sink surface area 112 of the main heat sink 110 and the heat sink surface area of the auxiliary heat sink 114 is therefore at least 11.66 to 1.

The battery unit 24 is configured to provide a continuous power supply to the drive unit 18 at a continuous current of at least 20 A and at most 45 A. In the present case, the battery unit 24 is configured to provide a continuous power supply of the drive unit 18 at a continuous current of at least 28 A. The battery unit 24 comprises a plurality of at least three battery cells 128 for this purpose. In the present case, the battery unit comprises a plurality of exactly three battery cells 128.

In FIG. 8, the motor 122 of the drive unit 18 is shown. The motor 122 is configured as a direct drive. The battery unit 24 is configured to operate the motor continuously for more than 3 minutes. In the present case, the motor 122 is configured as an electronically commutated electric motor.

The motor 122 has a diameter 124 of at least 30.00 mm and at most 48.00 mm perpendicular to the drive axis 30 of the drive unit 18. In the present case, the motor 122 has a diameter 124 of 38.00 mm perpendicular to the drive axis 30 of the drive unit 18.

The motor 122 has a maximum length 126 of at least 17.00 mm and at most 30.00 mm in parallel to the drive axis 30 of the drive unit 18. In the present case, the motor 122 has length 126 of 24.00 mm parallel to the drive axis 30 of the drive unit 18.

FIG. 9 shows the main heat sink 110 of the cooling unit 108 together with the circuit board 54 of the electronic unit 26 in a schematic perspective view.

As already described, the main heat sink 110 has a heat sink surface area 112 (cf. FIG. 9) of greater than 3000 mm². In the present case, the heat sink surface area 112 of the main heat sink 110 is at least 3500 mm². The heat sink surface area 112 of the main heat sink 110 is consequently at least 10.00% greater than the main outer surface area 74 (cf. FIGS. 4 and 5) of the circuit board 54 of the electronic unit 26. In the present case, the heat sink surface area 112 of the main heat sink 110 is at least 29.00% greater than the main outer surface area 74 of the circuit board 54 of the electronic unit 26.

A ratio between the total heat sink surface area (not shown) of the cooling unit 108, which in the present case comprises the heat sink surface area 112 of the main heat sink 110 and the heat sink surface area of the auxiliary heat sink 114, and a continuous current provided by the battery unit 24 to operate the drive unit 18, is at least 100 mm² to 1 A. In the present case, the cooling unit 108 has a total heat sink surface area of at least 3,800 mm² and in the present case the battery unit 24 provides a continuous current of 28 A for operation of the drive unit 18, such that the ratio between the continuous current and total heat sink surface area is at least 135 mm² to 1 A.

1. A machine tool device, comprising:
a housing unit including at least one handle segment and at least one drive segment;
a drive unit configured to drive a tool;
a tool holder configured to connect the tool to the drive unit;
a battery unit configured to supply power to the drive unit; and
an electronic unit configured to control the drive unit, the drive unit disposed in the at least one drive segment and the electronic unit and the battery unit disposed in the at least one handle segment,
wherein
a main extension plane of the electronic unit intersects a drive axis of the drive unit on a side facing away from the tool holder.

2. The machine tool device according to claim 1, wherein a projection surface area of the battery unit projected along an axis of motion of the battery unit has an outline at least substantially enclosing the electronic unit.

3. The machine tool device according to claim 1, wherein the main extension plane of the electronic unit is angled relative to the drive axis and an axis of motion of the battery unit.

4. The machine tool device of claim 1, wherein an axis of motion of the battery unit encloses an inclination angle with the main extension plane of the electronic unit of at least 20.00° and at most 50.00°.

5. The machine tool device according to claim 1, wherein an actuating element is disposed on the at least one handle segment and is configured to actuate the electronic unit, the actuating element having a greatest length perpendicular to the drive axis and corresponding to at least 25.00% of a greatest length of the at least one handle segment perpendicular to the drive axis.

6. The machine tool according to claim 5, wherein the electronic unit is bounded by a boundary plane running parallel to the drive axis intersecting the battery unit and/or the actuating element.

7. The machine tool device according to claim 5, wherein the electronic unit is bounded by a further boundary plane running parallel to the drive axis intersecting the actuating element.

8. The machine tool device according to claim 5, wherein the at least one handle segment, in a region of the actuating element, has a circumference of at least 130.00 mm and at most 140.00 mm.

9. The machine tool device according to claim 5, wherein a cross-section of the at least one handle segment in a region of the actuating element is oval and/or polygonal, having rounded corners and has a width of at least 35.00 mm and at most 40.00 mm and a height of at least 45.00 mm and at most 50.00 mm.

10. The machine tool device according to claim 1, wherein the electronic unit comprises a circuit board having an outer contour different from a rectangle.

11. The machine tool device according to claim 10, wherein the circuit board has rounded corners having a radius of 1.00 mm to 4.00 mm.

12. The machine tool device according to claim 10, wherein the circuit board has a length of at least 58.00 mm and at most 84.00 mm.

13. The machine tool device according to claim 10, wherein the circuit board has a greatest width of at least 28.00 mm and at most 45.00 mm.

14. The machine tool device according to claim 10, wherein the circuit board comprises two equally sized first side edges, each having a first angle of at least 13.00° and at most 33.00° with respect to a longitudinal direction of the circuit board.

15. The machine tool device according to claim 10, wherein the circuit board comprises two equally sized second side edges, each having a second angle of at least 5.0° and at most 25.0° with respect to a longitudinal direction of the circuit board.

16. The machine tool device according to claim 10, wherein the circuit board has a main outer surface area of at least 1850 mm² and at most 2700mm².

17. The machine tool device according to claim 1, wherein the housing unit comprises, in the at least one drive segment a section tapering toward the tool holder and enclosing an inclination angle of greater than 1.00° and less than 5.00° with a drive axis of the drive unit.

18. The machine tool device according to claim 1, wherein a cooling unit configured to cool the electronic unit comprises a main heat sink having a heat sink surface area of greater than 3000mm².

19. A machine tool device according to claim 18, wherein the cooling unit comprises at least one auxiliary heat sink connected to the main heat sink via at least one connecting element.

20. (canceled)

21. A machine tool system, comprising:
a machine tool according to claim 1; and
at least one tool configured to releasably connect with the tool holder.
